(19) United States
(12) Patent Application Publication
(10) Pub. No.: US 2026/0133253 A1
(43) Pub. Date: May 14, 2026

(54) ELECTRODE POTENTIAL ESTIMATION DEVICE AND METHOD

(71) Applicant: SAMSUNG SDI CO., LTD., Yongin-si (KR)

(72) Inventors: Yuuya ARIKAWA, Yongin-si (KR); Moonseok KWON, Yongin-si (KR); Bokhyun KA, Yongin-si (KR)

(73) Assignee: SAMSUNG SDI CO., LTD., Yongin-si (KR)

(21) Appl. No.: 19/374,824

(22) Filed: Oct. 30, 2025

(30) Foreign Application Priority Data
Nov. 8, 2024 (KR) 10-2024-0158335

(51) Int. Cl. G01R 31/388

(52) U.S. Cl. CPC G01R 31/388

(57) ABSTRACT

An electrode potential estimation device and method are provided. The electrode potential estimation device may include a storage device including an anode database configured to store charge/discharge differential profiles representing relationships between voltage change rates for unit capacities and capacities of anode half-cells, and a cathode database configured to store charge/discharge differential profiles representing relationships of anode half-cells obtained, a charging and discharging device configured to charge a battery cell to be diagnosed in a charge cycle and a discharging cycle, a measuring part configured to measure voltages and currents of the battery cell in the charge cycle and measure voltages and currents of the battery cell in the discharging cycle, and a controller configured to generate a charge/discharge differential profile.

### CROSS-REFERENCE TO RELATED APPLICATION

This application claims priority to Korean Patent Application No. 10-2024-0158335 filed in the Korean Intellectual Property Office on November 8, 2024, the entire contents of which are incorporated herein by reference.

### BACKGROUND

### (1) Field

The present disclosure relates to an electrode potential estimation device and method.

### (2) Description of the Related Art

The potential of cathode and anode of a lithium ion battery are relevant in diagnosing the life or deterioration of the battery, but it is challenging to accurately measure the potential of the cathode and anode.

Generally, a three-electrode cell is manufactured using a cathode, an anode, and a reference electrode, and the potential of each of the cathode and anode is measured. However, because the method of measuring potential using the three-electrode cell is affected by the position and shape of the reference electrode, accurate measurement of the potential may be challenging. In addition, because the three-electrode cell has a different structure from a battery cell, the three-electrode cell may be manufactured separately.

### SUMMARY

At least one example embodiment includes an electrode potential estimation device and a method capable of estimating the potential of an anode or a cathode of a battery cell to be diagnosed without manufacturing a separate three- electrode cell for potential measurement.

According to an example aspect, an electrode potential estimation device may be provided. The electrode potential estimation device includes a storage device including an anode database configured to store charge/discharge differential profiles representing relationships between voltage change rates for unit capacities and capacities of anode half-cells obtained by setting at least one of material characteristics of cathode active materials, a C-rate, a charge/discharge as variables, and a cathode database configured to store charge/discharge differential profiles representing relationships of anode half-cells obtained by setting at least one of material characteristics of a cathode active material, C-rate, a charge/discharge voltage as variables,. The electrode potential estimation device also includes a charging and discharging device configured to charge a battery cell to be diagnosed in a charge cycle and discharge the battery cell in a discharging cycle, and a measuring part configured to measure voltages and currents of the battery cell in the charge cycle and measure voltages and currents of the battery cell in the discharging cycle,. The electrode potential estimation device further includes a controller configured to generate a charge/discharge differential profile based on the voltages and currents of the battery cell measured in the charge cycle and the discharge cycle, extract an anode half-cell and a cathode half-cell having a charge/discharge differential profile matching the charge/discharge differential profile of the battery cell by referencing the anode database and the cathode database, and estimate a full charge state for each of the cathode and anode of the battery cell based on information of the extracted anode half-cell and the cathode half-cell.

The controller may be configured to extract charge/discharge differential profiles of candidate anode half-cells from the anode database, extract charge/discharge differential profiles of candidate cathode half-cells from the cathode database, generate charge/discharge differential profiles of candidate full cells by combining each of charge/discharge differential profiles of the candidate anode half-cells with each of charge/discharge differential profiles of the candidate cathode half-cells, and extract the anode half-cell and the cathode half-cell through matching each of charge/discharge differential profiles of each candidate full cells with the charge/discharge differential profile of the battery cell.

The controller may be configured to determine a charge/discharge differential profile of one candidate full cell that has a matching rate that is higher than or equal to a set matching rate with the charge/discharge differential profile of the battery cell and has the highest matching rate, among the charge/discharge differential profiles of the candidate full cells, and the extracted anode half-cell and cathode half-cell may correspond to the anode half-cell and cathode half-cell corresponding to the determined one candidate full cell.

The controller may be configured to extract a charge/discharge differential profiles of the candidate anode half-cells from the anode database based on at least one of the material characteristics of anode active materials of the battery cell, a C-rate, and a charge/discharge voltage, and extract a charge/discharge differential profiles of the candidate cathode half-cells from the cathode database based on the charge/discharge voltage of the battery cell and charge/discharge voltages of the candidate anode half-cells.

The controller may be configured to estimate capacities of the battery cell based on the currents of the battery cell, generate a charge/discharge profile representing the relationships between the voltages and capacities of the battery cell, and generate the charge/discharge differential profile based on the charge/discharge profile.

The material characteristics of the anode active materials may include an addition ratio of silicon.

According to another example aspect, a method for estimating an electrode potential of a battery cell in an electrode potential estimation device connected to the battery cell to be diagnosed may be provided. The method includes charging the battery cell in a charge cycle and discharging the battery cell in a discharge cycle, measuring voltages and currents of the battery cell during the charging cycle, measuring voltages and currents of the battery cell during the discharge cycle, generating a differential profile representing relationships between voltage change rates for unit capacities and capacities of the battery cell based on the voltages and currents of the battery cell measured in the charge cycle or the discharge cycle, respectively, extracting an anode half-cell and a cathode half-cell having a differential profile matching the differential profile of the battery cell by referencing an anode database storing differential profiles for anode half-cells and a cathode database storing differential profiles for cathode half-cells, and estimating a full charge state for each of a cathode and an anode of the battery cell based on information of the extracted cathode half-cell and anode half-cell.

The method may further include setting at least one of material characteristics of anode active materials, a C-rate, and a charge/discharge voltage as variables, and obtaining a differential profile of an anode half-cell while changing at least one variable, and setting at least one of material characteristics of cathode active materials, a C-rate, and a charge/discharge voltage as variables, and obtaining a differential profile for cathode half-cell while changing at least one variable.

The extracting may include extracting differential profiles of candidate anode half-cells from the anode database, extracting differential profiles of candidate cathode half-cells from the cathode database, generating differential profiles of candidate full cells by combining each of the differential profiles of the candidate anode half-cells and each of the differential profiles of the candidate cathode half-cells, and extracting the anode half-cell and the cathode half-cell by matching the differential profile of each of the candidate full cells with the differential profile of the battery cell.

The extracting the anode half-cell and the cathode half-cell by matching may include determining one candidate full cell which has a matching rate that is higher than or equal to a set matching rate with the differential profile of the battery cell and that has the highest matching rate, among the differential profiles of the candidate full cells, and extracting the anode half-cell and the cathode half-cell corresponding to the one candidate full cell.

The extracting differential profiles of candidate anode half-cells may include extracting the differential profiles of the candidate anode half-cells from the anode database based on at least one of the material characteristics of the anode active materials, the C-rate, and the charge/discharge voltage of the battery cell, and the extracting differential profiles of candidate cathode half-cells may include extracting the differential profiles of the candidate cathode half-cell from the cathode database based on the charge/discharge voltage of the battery cell and the charge/discharge voltages of the candidate anode half-cells.

The differential profile may be or include a charge differential profile or a discharge differential profile.

The generating the differential profile may include estimating capacities of the battery cell based on the currents of the battery cell, generating a charge/discharge profile representing the relationships between the voltages and capacities of the battery cell, and generating the differential profile based on the charge/discharge profile.

The material characteristics of the anode active materials may include an addition ratio of silicon.

### BRIEF DESCRIPTION OF THE DRAWINGS

FIG. 1 is a drawing illustrating an electrode potential estimation device according to one example embodiment.

FIG. 2 is a diagram illustrating an example of information stored in the storage device illustrated in FIG. 1.

FIG. 3 and FIG. 4 are diagrams illustrating examples of charge/discharge profiles and charge/discharge differential profiles obtained by changing the charge voltage for an anode half-cell.

FIG. 5 is a flowchart illustrating an electrode potential estimation method according to one example embodiment.

FIG. 6 is a flowchart illustrating a method for determining one candidate full cell for diagnosis of a battery cell according to an example embodiment.

FIG. 7 is a drawing illustrating an anode half-cell and a cathode half-cell determined by a curve matching method according to an example embodiment.

FIG. 8 is a drawing illustrating an electrode potential estimation device according to another example embodiment.

FIG. 9 is a drawing illustrating an example of a battery pack to which an electrode potential estimation device according to one example embodiment is applied.

### DETAILED DESCRIPTION OF THE EMBODIMENTS

Example embodiments is described more fully hereinafter with reference to the accompanying drawings, however, the example embodiments may be embodied in different forms and may not be construed as limited to the embodiments set forth herein. Rather, these embodiments are provided so that this disclosure is thorough and complete, and fully conveys example implementations to those skilled in the art. The drawings and description are to be regarded as illustrative in nature and not restrictive. Like reference numerals designate like elements throughout the specification. In the flowchart described with reference to the drawings in this specification, the order of operations may be changed, several operations may be merged, some operations may be divided, and specific operations may not be performed.

Throughout the specification and claims, when a part is referred to "include" a certain element, it may mean that it may further include other elements rather than exclude other elements, unless indicated otherwise.

In addition, expressions described in the singular may be interpreted in the singular or plural unless explicit expressions such as "one" or "single" are used.

Furthermore, terms including an ordinal number, such as first, second, and the like, may be used to describe various elements, but the elements are not limited by the terms. The above terms are used only for the purpose of distinguishing one element from another element. For example, without departing from the scope of the present disclosure, a first element may be referred to as a second element, and similarly, a second element may be referred to as a first element.

Furthermore, when a component is referred to be "connected" with another component, it includes not only the case where two components are "directly connected" but also the case where two components are "indirectly or non-contactedly connected" with another component interposed therebetween, or the case where two components are "electrically connected." On the other hand, when an element is referred to as “directly connected” to another element, it may be understood that no other element exists in the middle.

When the terms "about" or “substantially” are used in this specification in connection with a numerical value, it is intended that the associated numerical value include a tolerance of ±10% around the stated numerical value. When ranges are specified, the range includes all values therebetween such as increments of 0.1%.

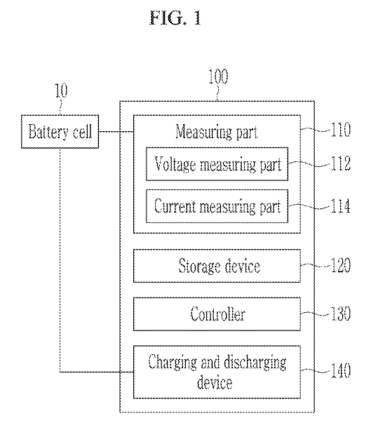

FIG. 1 is a drawing illustrating an electrode potential estimation device according to one example embodiment.

Referring to FIG. 1, the electrode potential estimation device 100 may include a measuring part 110, a storage device 120, a controller 130, and a charging and discharging device 140.

The charging and discharging device 140 may be connected to a battery cell 10. The charging and discharging device 140 may be configured to charge or discharge the battery cell 10 according to the charging and discharging control of the controller 130. For example, the charging and discharging device 140 may charge the battery cell 10 in a constant current (CC) mode up to a set charge voltage (e.g., 4.25 V) at a set C-rate (e.g., 0.05C) in a charge cycle according to the charging and discharging control of the controller 130, and may discharge the battery cell 10 in a CC mode up to a set discharge voltage (e.g., 2.5 V) at a set C-rate (e.g., 0.05C) in a discharge cycle.

The measuring part 110 may be configured to measure voltages and currents of the battery cell 10 while the battery cell 10 is being charged or discharged during the charge and discharge cycle of the battery cell 10.

The battery cell 10 may be or include, for example, a lithium ion cell. The battery cell 10 may be composed of or include a cathode, an anode, a separator, and an electrolyte. The anode is considered a negative electrode and the cathode is considered a positive electrode. The electrolyte may be between the cathode and the separator, and between the anode and the separator. The battery cell 10 may be charged by moving lithium ions from the cathode to the anode, and storing lithium ions in the anode. As lithium ions from the anode move to the cathode, and electrons separated from the lithium ions move along the conductor, electricity is generated and the battery cell 10 may be discharged. The cathode active material, which is the material that substantially forms the cathode, may be made using at least one of nickel, cobalt, aluminum, manganese, and the like. For example, a nickel cobalt aluminum oxide (NCA) cathode may include or be composed primarily of nickel, with cobalt, aluminum, and lithium oxide. The anode active material, which is the material that forms the anode, can mainly be or include graphite, which may stably store many ions. Silicon has the advantages of higher energy density, shorter charging time, and higher output compared to graphite, but swelling may occur when charging and discharging repeatedly. Accordingly, a small amount (e.g., about 1 to about 10%) of silicon may be added to graphite material that may be used as the anode active material.

The storage device 120 may store the measured charge/discharge profile and charge/discharge differential profile for each of the anode and cathode, e.g., an anode half-cell and a cathode half-cell. The charge/discharge profile may represent the correspondence relationships between capacities and voltages, and the charge/discharge differential profile may represent the correspondence relationships between the differential voltages (that is, voltage change rates) for unit capacity and capacities. The storage device 120 may store the measured charge/discharge profile and charge/discharge differential profile while changing the charge voltage and discharge voltage according to the C-rate for each of the anode half-cell and the cathode half-cell. In some example embodiments, the C-rate may be a low rate in the range of about 0.2C to about 0.01C.

Meanwhile, depending on the material properties of silicon, the cathode with added silicon has a characteristic in which a discharge curve changes depending on the depth of charge. Therefore, according to an example embodiment, the storage device 120 may store the charge/discharge profile and the charge/discharge differential profile for the cathode half-cell according to each of addition ratios of silicon.

The measuring part 110 may be configured to measure the voltages of the battery cell 10 to be diagnosed, as well as the charge currents and discharge currents of the battery cell 10.

The measuring part 110 may include a voltage measuring part 112 and a current measuring part 114.

The voltage measuring part 112 may be configured to measure cathode potentials and anode potentials of the battery cell 10, and may measure voltages of the battery cell 10 using the differences between the measured cathode potentials and anode potentials. The current measuring part 114 may measure the charge currents and discharge currents of the battery cell 10 via, e.g., an ammeter (A) provided on the charging and discharging path of the battery cell 10.

The voltage measurement part 112 may be configured to transmit information about the measured voltages of the battery cell 10 to the controller 130. The current measuring part 114 may be configured to transmit information about the measured currents of the battery cell 10 to the controller 130.

The controller 130 may be configured to estimate the capacities of the battery cell 10 based on the currents of the battery cell 10 measured by the current measuring part 114.

The controller 130 may generate a charge/discharge profile and a charge/discharge differential profile of the battery cell 10 based on the voltages and capacities of the battery cell 10.

The controller 130 may generate charge/discharge differential profiles of full cells by combining the charge/discharge differential profiles of the anode half-cells stored and the charge/discharge differential profiles of the cathode half-cells, in the storage device 120, and may estimate a full charge state of each of the cathode and anode of the battery cell 10 by using a curve matching method between the charge/discharge differential profiles of the full cells and the charge/discharge differential profile of the battery cell 10.

In some example embodiments, the controller may extract charging differential profiles of candidate anode half-cells in the storage device based on at least one of anode characteristics of the battery cell 10, such as silicon addition ratio, charge voltage, and C-rate, and may extract charging differential profiles of candidate cathode half-cells in the storage device 120 based on the charge voltage of the battery cell 10 and the charge voltage of the candidate anode half-cells. The controller may generate charging differential profiles of the candidate full cells by combining the charging differential profiles of each of the candidate anode half-cells, and the charging differential profiles of each of the candidate cathode half-cells, and may select one candidate full cell that matches the charging differential profile of the battery cell 10 among the charging differential profiles of the candidate full cells by matching the charging differential profile of the candidate full cells with the charge differential profile of the battery cell 10. The controller 130 may estimate the full charge state of each of the cathode and anode of the battery cell 10 from the charge voltage of each of the cathode half-cell and anode half-cell of the selected candidate full cell.

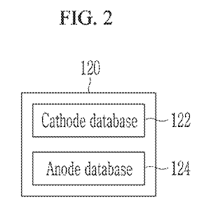

FIG. 2 is a diagram illustrating an example of information stored in the storage device illustrated in FIG. 1.

Referring to FIG. 2, the storage device 120 may include a cathode database 122 and an anode database 124.

The cathode database 122 may be configured to store charge/discharge profiles obtained by setting C-rate, charge voltage, and discharge voltage as variables for the cathode half-cell, and charge/discharge differential profiles calculated from the charge/discharge profiles.

A charge/discharge profile for the cathode half-cell may be obtained by charging and discharging the cathode half-cell based on a first charge voltage and a first discharge voltage at a first C-rate (e.g., about 0.01C). Charge/discharge profiles for the cathode half-cell may be obtained by charging and discharging the cathode half-cell while fixing the first C-rate and the first discharge voltage, and changing only the first charge voltage. In an example, charge/discharge profiles for the cathode half-cell may be obtained by charging and discharging the cathode half-cell while fixing the first C-rate and the first charge voltage, and changing only the first discharge voltage. Next, the first C-rate (e.g., about 0.02C) may be changed, and a charge/discharge profile for the cathode half-cell may be obtained by charging and discharging the cathode half-cell based on the first charge voltage and the first discharge voltage at the changed first C-rate (e.g., 0.02C). Charge/discharge profiles for the cathode half-cell may be obtained by charging and discharging the cathode half-cell while fixing the first C-rate and the first discharge voltage, and changing only the first charge voltage, and charge/discharge profiles for the cathode half-cell may be obtained by charging and discharging the cathode half-cell while fixing the first C-rate and the first charge voltage and changing only the first discharge voltage. In this way, charge/discharge profiles for the cathode half-cell may be generated for each of C-rates, charge voltages, and discharge voltages, and charge/discharge differential profiles may be calculated for each of C-rates, charge voltages, and discharge voltages from the charge/discharge profiles for each of C-rates, charge voltages, and discharge voltages. In addition, charge/discharge profiles and charge/discharge differential profiles for the cathode half-cell may be obtained in the same manner as above while changing the cathode active materials.

The charge/discharge profiles and charge/discharge differential profiles for the cathode half-cell obtained in this manner may be stored in the cathode database 122.

The anode database 124 is configured to store charge/discharge profiles obtained by setting C-rate, charge voltage, and discharge voltage as variables for the anode half-cell, and charge/discharge differential profiles calculated from the charge/discharge profiles.

According to an example embodiment, the anode database 124 may store charge/discharge profiles obtained by setting C-rate, charge voltage, and discharge voltage as variables for the anode half-cell according to anode active materials, and charge/discharge differential profiles calculated from the charge/discharge profiles.

The method for obtaining the charge/discharge profiles for the anode half-cell may be similar or identical to the method for obtaining the charge/discharge profiles for the cathode half-cell.

A charge/discharge profile for the anode half-cell may be obtained by charging and discharging the cathode half-cell based on a second charge voltage and a second discharge voltage at a first C-rate (e.g., about 0.01C). Charge/discharge profiles for the anode half-cell may be obtained by charging and discharging the anode half-cell while fixing the first C-rate and the second discharge voltage, and changing only the second charge voltage. In an example, charge/discharge profiles for the anode half-cell may be obtained by charging and discharging the anode half-cell while fixing the first C-rate and the second charge voltage, and changing only the second discharge voltage. Next, the first C-rate (e.g., about 0.02C) may be changed, and a charge/discharge profile for the anode half-cell may be obtained by charging and discharging the anode half-cell based on the second charge voltage and the second discharge voltage at the changed first C-rate (e.g., about 0.02C). Charge/discharge profiles for the anode half-cell may be obtained by charging and discharging the anode half-cell while fixing the first C-rate and the second discharge voltage and changing only the second charge voltage, and charge/discharge profiles for the anode half-cell may be obtained by charging and discharging the anode half-cell while fixing the first C-rate and the second charge voltage and changing only the second discharge voltage. Accordingly, charge/discharge profiles for the anode half-cell may be generated for each of C-rates, charge voltages, and discharge voltages, and charge/discharge differential profiles may be calculated for each of C-rates, charge voltages, and discharge voltages from the charge/discharge profiles for each of C-rates, charge voltages, and discharge voltages.

In examples, charge/discharge profiles and charge/discharge differential profiles for the anode half-cell may be obtained in the same manner as described above while changing the anode active materials. At this time, a change in the anode active materials may indicate a change in the addition ratio of silicon.

The charge/discharge profiles and charge/discharge differential profiles for the anode half-cell obtained in this manner may be stored in the anode database 124.

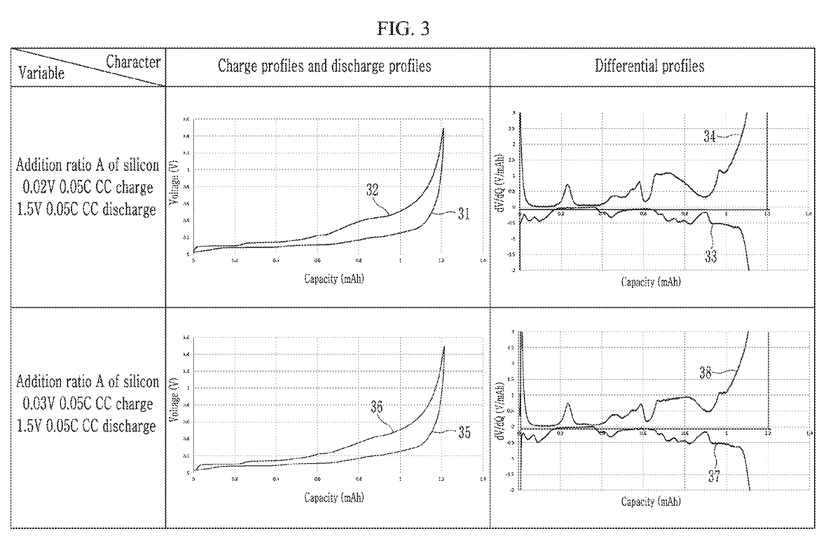

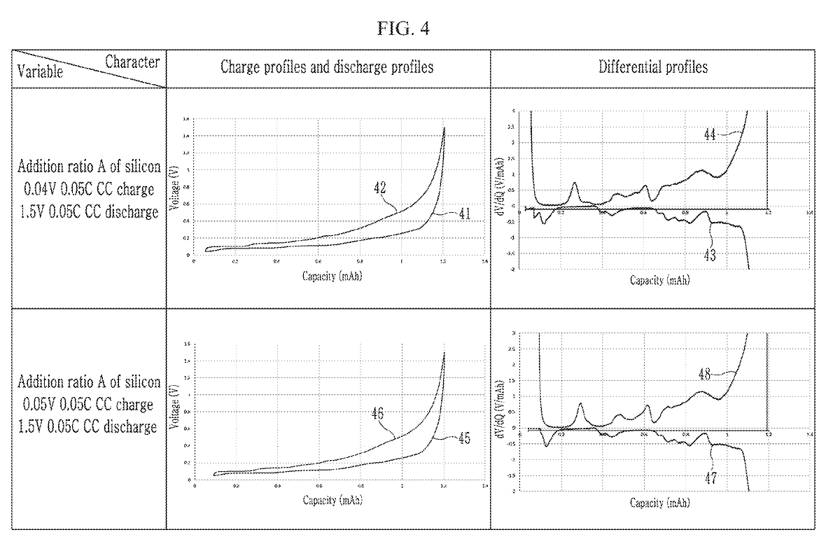

FIG. 3 and FIG. 4 are diagrams illustrating examples of charge/discharge profiles and charge/discharge differential profiles obtained by changing the charge voltage for an anode half-cell.

Referring to FIG. 3, an anode half-cell may be manufactured, which includes anode active materials having the addition ratio A of silicon and a lithium metal referred to as a reference electrode.

The charging and discharging device 140 may be configured to charge the anode half-cell in a constant current (CC) mode at a C-rate of about 0.05C to a charge voltage of about 0.02 V during a charge cycle, and may discharge the anode half-cell in a CC mode at a C-rate of about 0.05C to a discharge voltage of about 1.5 V during a discharge cycle.

The measuring part 110 may measure the voltages and currents of the anode half-cell in the charge cycle, and the controller 130 may be configured to estimate the capacities of the anode half-cell based on the measured currents, and may generate a charge curve 31, which is a charge profile using the capacities as a horizontal coordinate and the voltages as a vertical coordinate. In addition, the measuring part 110 may measure the voltages and currents of the anode half-cell in the discharge cycle, and the controller 130 may estimate the capacities of the anode half-cell based on the measured currents, and may generate a discharge curve 32, which is a discharge profile using the capacities as the horizontal coordinate and the voltages as the vertical coordinate.

The controller 130 may generate a charge differential curve 33, which is a charge differential profile that shows the relationships between the differential voltages (voltage change rates) for unit capacities and capacities using the charge curve 31, and may generate a discharge differential curve 34, which is a discharge differential profile that shows the relationships between the differential voltages (voltage change rates) for unit capacities and capacities using the discharge curve 32.

Next, the charging and discharging device 140 may change the charge voltage to about 0.03V while keeping all other variables fixed, charge the anode half-cell during a charge cycle, and discharge the anode half-cell in a discharge cycle.

The measuring part 110 may measure the voltages and currents of the anode half-cell in the charge cycle and measure the voltages and currents of the anode half-cell in a discharge cycle. The controller 130 may generate a charge curve 35 of the anode half-cell using the voltages and capacities of the anode half-cell in the charge cycle, and may generate a discharge curve 36 of the anode half-cell using the voltages and capacities of the anode half-cell in the discharge cycle. Additionally, the controller 130 may generate a charge differential curve 37 of the anode half-cell using the charge curve 35, and may generate a discharge differential curve 38 of the anode half-cell using the discharge curve 36.

Referring to FIG. 4, the charging and discharging device 140 may change the charge voltage to about 0.04V while keeping all other variables fixed, charge the anode half-cell during the charge cycle, and discharge the anode half-cell during a discharge cycle.

The measuring part 110 may measure the voltages and currents of the anode half-cell in the charge cycle and measure the voltages and currents of the anode half-cell in the discharge cycle. The controller 130 may generate a charge curve 41 of the anode half-cell using the voltages and capacities of the anode half-cell in the charge cycle, and may generate a discharge curve 42 of the anode half-cell using the voltages and capacities of the anode half-cell in the discharge cycle. In an example, the controller 130 may generate a charge differential curve 43 of the anode half-cell using the charge curve 41, and may generate a discharge differential curve 44 of the anode half-cell using the discharge curve 42.

In examples, the charging and discharging device 140 may change the charge voltage to about 0.05V while keeping all other variables fixed, charge the anode half-cell during a charge cycle, and discharge the anode half-cell during a discharge cycle.

The measuring part 110 may be configured to measure the voltages and currents of the anode half-cell in the charge cycle, and measure the voltages and currents of the anode half-cell in the discharge cycle. The controller 130 may generate a charge curve 45 of the anode half-cell using the voltages and capacities of the anode half-cell in the charge cycle, and may generate a discharge curve 46 of the anode half-cell using the voltages and capacities of the anode half-cell in the discharge cycle. Additionally, the controller 130 may generate a charge differential curve 47 of the anode half-cell using the charge curve 45, and may generate a discharge differential curve 48 of the anode half-cell using the discharge curve 46.

In an example, an anode half-cell may be manufactured, which includes anode active materials having the addition ratio B of silicon, and charge/discharge profiles and charge/discharge differential profiles for the anode half-cell may be generated using the same method as described above.

The charge/discharge profiles and charge/discharge differential profiles for the anode half-cell for each of the addition ratios of silicon, C-rates, charge voltages, and discharge voltages obtained in this manner may be stored in the anode database (124 in FIG. 2).

In addition, a cathode half-cell may be manufactured, which includes a cathode having cathode active materials and a lithium metal referred to as a reference electrode, and by the same method as described above, charge/discharge profiles and charge/discharge differential profiles for the cathode half-cell for each of the cathode active materials, C-rates, charge voltages, and discharge voltages may be generated, and the charge/discharge profiles and charge/discharge differential profiles for the cathode half-cell may be stored in the cathode database (122 in FIG. 2).

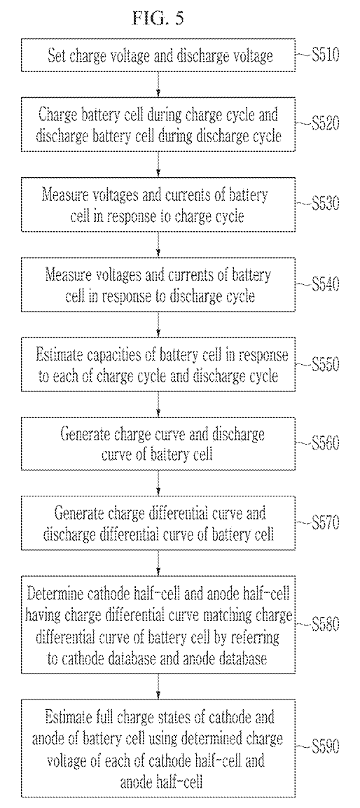

FIG. 5 is a flowchart illustrating an electrode potential estimation method according to one example embodiment.

Referring to FIG. 5, the charging and discharging device 140 of the electrode potential estimation device 100 may connect the battery cell 10 to be diagnosed and may set a charge voltage and a discharge voltage (S510).

The charging and discharging device 140 of the electrode potential estimation device 100 may charge the battery cell 10 during a charge cycle and discharge the battery cell 10 during a discharge cycle based on the charge voltage and the discharge voltage (S520).

The measuring part 110 of the electrode potential estimation device 100 may measure the voltages and currents of the battery cell 10 in response to the charge cycle (S530) and measure the voltages and currents of the battery cell 10 in response to the discharge cycle (S540).

The measuring part 110 of the electrode potential estimation device 100 may transmit the voltages and currents of the battery cell 10 measured in the charge cycle, and the voltages and currents of the battery cell 10 measured in the discharge cycle, to the controller 130.

The controller 130 of the electrode potential estimation device 100 may estimate capacities of the battery cell 10 based on the currents of the battery cell 10 measured in response to the charge cycle, and may estimate the capacities of the battery cell 10 based on the currents of the battery cell 10 measured in response to the discharge cycle (S550).

The controller 130 of the electrode potential estimation device 100 may generate a charge curve of the battery cell 10 based on the voltages and capacities of the battery cell 10 obtained in the charge cycle, and may generate a discharge curve of the battery cell 10 based on the voltages and capacities of the battery cell 10 obtained in the discharge cycle (S560).

The controller 130 of the electrode potential estimation device 100 may generate a charge differential curve of the battery cell 10 based on the charge curve of the battery cell 10, and may generate a discharge differential curve of the battery cell 10 based on the discharge curve of the battery cell 10 (S570).

The controller 130 of the electrode potential estimation device 100 may determine a cathode half-cell and an anode half-cell having a charge differential curve matching the charge differential curve of the battery cell 10 by referring to the cathode database 122 and the anode database 124 stored in the storage device 120 (S580). For example, the controller 130 of the electrode potential estimation device 100 may generate charge differential curves of candidate full cells by combining each of the charge differential curves of the cathode half-cells stored in the cathode database 122 and each of the charge differential curves of the anode half-cell stored in the anode database 124, match the charge differential curves of the candidate full cells with the charge differential curve of the battery cell 10, extract one candidate full cell having the highest matching rate that is equal to or higher than a set matching rate, and determine the cathode half-cell and the anode half-cell from the extracted one candidate full cell.

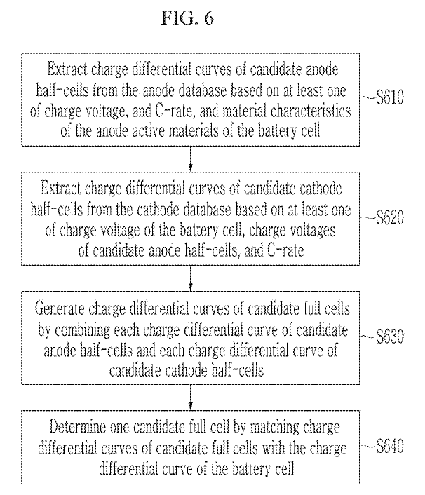

This is explained in more detail below with reference to FIG. 6.

FIG. 6 is a flowchart illustrating a method for determining one candidate full cell for diagnosis of a battery cell, according to an example embodiment.

Referring to FIG. 6, the controller of the electrode potential estimation device 100 may extract charge differential curves of candidate anode half-cells from the anode database 124 based on at least one of the charge voltage, and the C-rate, and the material characteristics of the anode active materials of the battery cell 10, such as the addition ratio of silicon (S610).

The controller 130 of the electrode potential estimation device 100 may extract charge differential curves of candidate cathode half-cells from the cathode database 122 based on at least one of the charge voltage of the battery cell 10, the charge voltages of candidate anode half-cells, and C-rate (S620). A full cell may be implemented by combining a cathode half-cell and an anode half-cell, and when the charge voltage of the battery cell 10 is considered as the charge voltage of the full cell, the charge voltage of the available cathode half-cell may be estimated from the charge voltage of the battery cell 10 and the charge voltages of each of the candidate anode half-cells. The controller 130 of the electrode potential estimation device 100 may extract the charge differential curves of the candidate cathode half-cells from the cathode database 122 based on the charge voltage of the battery cell 10 and the charge voltages of each of the candidate anode half-cells.

The controller 130 of the electrode potential estimation device 100 may generate charge differential curves of candidate full cells by combining each charge differential curve of candidate anode half-cells and each charge differential curve of candidate cathode half-cells (S630).

The controller 130 of the electrode potential estimation device 100 may match the charge differential curves of candidate full cells with the charge differential curve of the battery cell 10, and determine one candidate full cell that has a matching rate that is higher than or equal to a set matching rate and that has the highest matching rate (S640).

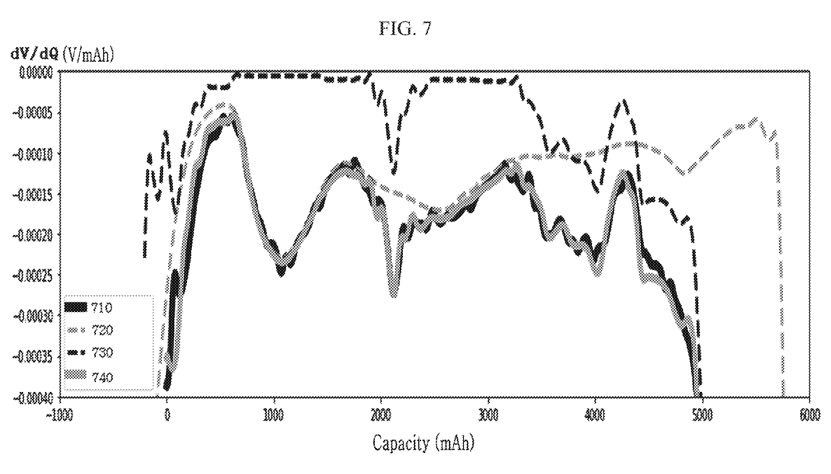

FIG. 7 is a drawing illustrating an anode half-cell and a cathode half-cell determined by a curve matching method according to an example embodiment.

In FIG. 7, 710 represents a charge differential curve of a battery cell 10, and 720 represents a charge differential curve of a candidate cathode half-cell. 730 represents a charge differential curve of the candidate anode half-cell, and 740 represents a charge differential curve of the candidate full cell which is the combination of the charge differential curves of the candidate cathode half-cell and the candidate anode half-cell.

Referring to FIG. 7, the controller of the electrode potential estimation device 100 may generate a charge differential curve 740 of the candidate full cell by combining the charge differential curve 720 of the candidate cathode half-cell and the charge differential curve 730 of the candidate anode half-cell, and may match the charge differential curve 740 of the candidate full cell with the charge differential curve 710 of the battery cell 10.

The controller 130 of the electrode potential estimation device 100 may select the charge differential curve 740 of the candidate full cell for diagnosis of the battery cell 10 when the result of matching the charge differential curve 740 of the candidate full cell with the charge differential curve 710 of the battery cell 10 is higher than the set matching rate and has a higher matching rate than the result of matching the charge differential curves of the remaining candidate full cells with the charge differential curve 710 of the battery cell 10.

Referring back to FIG. 5, the controller 130 of the electrode potential estimation device 100 may estimate the full charge state of the cathode of the battery cell 10 and the full charge state of the anode of the battery cell 10 using the determined charge voltages of each of the positive half-cell and the negative half-cell (S590).

In FIG. 5 to FIG. 7, the full charge states of the cathode and anode of the battery cell 10 may be estimated by using the charge differential curve of the battery cell 10, but similarly to the method described above, the full charge states of the cathode and anode of the battery cell 10 may also be estimated by using the discharge differential curve of the battery cell 10.

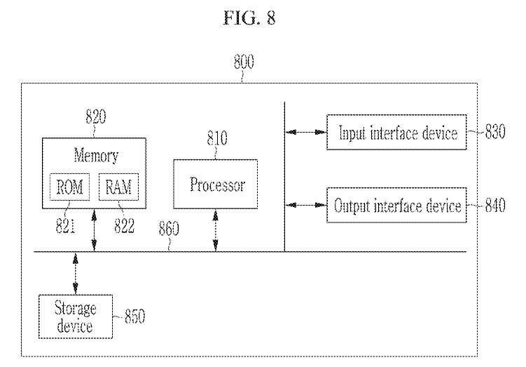

FIG. 8 is a drawing illustrating an electrode potential estimation device according to another example embodiment.

Referring to FIG. 8, the electrode potential estimation device 800 may represent a computing device in which the electrode potential estimation method described above is implemented.

The electrode potential estimation device 800 may include at least one of a processor 810, a memory 820, an input interface device 830, an output interface device 840, and a storage device 850. Each component may be connected by a bus 860, and may communicate with each other. Additionally, each component may be connected through an individual interface or individual bus centered on the processor 810, rather than via the common bus 860.

The processor 810 may be implemented as one of various types of processors such as an application processor (AP), a central processing unit (CPU), a graphics processing unit (GPU), and the like, and may be or include any semiconductor device that executes a command stored in the memory 820 or in storage device 850. The processor 810 may execute program commands stored in at least one of the memory 820 and the storage device 850. This processor 810 stores program commands for implementing at least some functions of the measuring part 110, the controller 130, and the charging and discharging device 140 illustrated in FIG. 1 in the memory 820, and may perform the operation of the electrode potential estimation device 100 described with reference to FIG. 1 to FIG. 7.

The memory 820 and storage device 850 may include various forms of volatile or non-volatile storage media. For example, the memory 820 may include read-only memory (ROM) 821 and random access memory (RAM) 822. In an example embodiment, the memory 820 may be disposed inside or outside the processor 810, and the memory 820 may be connected to the processor 810 through various known means.

According to an example embodiment, the memory 820 and the storage device 850 may include the storage device 120 illustrated in FIG. 1.

The input interface device 830 may be configured to provide data to the processor 810. In some example embodiments, the input interface device 830 may provide voltages and currents of the battery cell 10 to the processor 810.

The output interface device 840 may be configured to output data from the processor 810. In some example embodiments, the output interface device 840 may output the full charge status of each of the anode and cathode of the battery cell 10 illustrated in FIG. 1.

In some example embodiments, the input interface device 830 and the output interface device 840 may be or include network interface devices connected to a network.

At least some of the electrode potential estimation methods according to the example embodiments may be implemented as a program or software running on a computing device, and the program or software may be stored on a computer-readable medium.

For example, at least some of the electrode potential estimation methods may be implemented in hardware that can be electrically connected to a computing device.

Additionally, the electrode potential estimation device 100 described above may be applied to a battery pack.

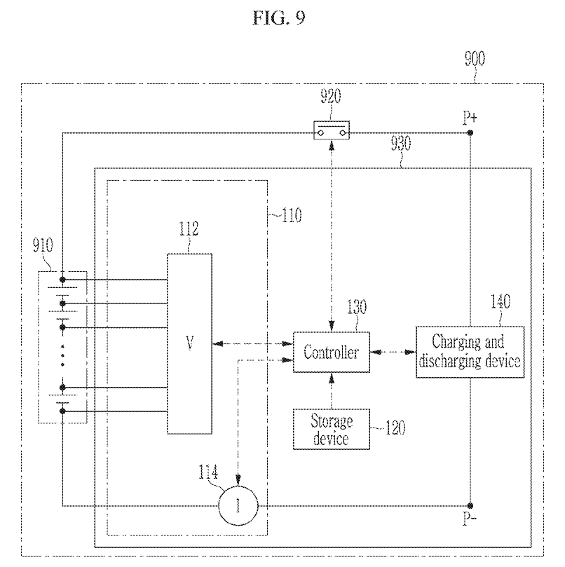

FIG. 9 is a drawing illustrating an example of a battery pack to which an electrode potential estimation device according to one example embodiment is applied.

Referring to FIG. 9, a battery pack 900 may include a battery 910, a relay 920, and a battery management system (BMS) 930.

The battery 910 may include a plurality of battery cells electrically connected to each other in series and/or in parallel. For example, the plurality of battery cells may be connected in series.

The relay 920 may be configured to control the current path during charging and discharging of the battery 910. The relay 920 may be connected between the battery 910 and a terminal P+.

The relay 920 can be turned on and off in response to a switching signal from the BMS 930. The relay 920 may be or include a mechanical contactor that is turned on and off by the magnetic force of a coil, or a semiconductor switch such as a metal oxide semiconductor field effect transistor (MOSFET).

The BMS 930 may include an electrode potential estimation device as illustrated in FIG. 1. That is, the BMS 930 may include a measuring part 110, a storage device 120, a controller 130, and a charging and discharging device 140.

The charging and discharging device 140 may charge and discharge the battery 910 according to the charging and discharging control of the controller 130.

The voltage measuring part 112 of the measuring part 110 may be connected to the positive terminal and negative terminal of each of the plurality of battery cells included in the battery 910, measure the voltage between two terminals of each of the battery cells, and transmit the measured voltages to the controller 130.

The current measuring part 114 may be connected in series to the battery 910 through a current path between the battery 910 and a terminal P-. The current measuring part 114 may measure the charge and discharge current flowing through the battery 910 and transmit the measured charge and discharge current to the controller 130.

The controller 130 may be connected to the relay 920, the measuring part 110, the storage device 120, and the charging and discharging device 140.

The controller 130 may estimate the potential state of the anode and cathodes for each battery cell based on the electrode estimation method described above.

The controller 130 may be implemented in hardware using at least one of application specific integrated circuits (ASICs), digital signal processors (DSPs), digital signal processing devices (DSPDs), programmable logic devices (PLDs), field programmable gate arrays (FPGAs), microprocessors, application processors (APs), central processing units (CPUs), graphic processing units (GPUs), and other electrical units for performing functions.

The controller 130 may estimate the potential state of the anode and cathode for each battery cell, and may also estimate the deterioration of each battery cell based on the potential state of the anode and cathode for each battery cell according to the charge and discharge cycles and the potential state of the anode and cathode for each battery cell at the beginning of life (BOL).

According to at least one example embodiment of the present disclosure, the potentials of the anode and cathode of a battery cell to be diagnosed may be estimated using information of electrodes stored in a database without manufacturing a three-electrode cell for potential measurement.

Example embodiments have been disclosed herein, and although specific terms are employed, the terms are to be interpreted in a generic and descriptive sense only and not for purpose of limitation. In some instances, as would be apparent to one of ordinary skill in the art as of the filing of the present application, features, characteristics, and/or elements described in connection with a particular example embodiment may be used singly or in combination with features, characteristics, and/or elements described in connection with other example embodiments unless otherwise indicated. Accordingly, it is understood by those of skill in the art that various changes in form and details may be made without departing from the spirit and scope of the present disclosure as set forth in the following claims.

What is claimed is:

1. An electrode potential estimation device comprising:
a storage device including an anode database configured to store charge/discharge differential profiles representing relationships between voltage change rates for unit capacities and capacities of anode half-cells obtained by setting at least one of material characteristics of cathode active materials, a C-rate, a charge/discharge as variables, and a cathode database configured to store charge/discharge differential profiles representing relationships of anode half-cells obtained by setting at least one of material characteristics of a cathode active material, C-rate, a charge/discharge voltage as variables,
a charging and discharging device configured to charge a battery cell to be diagnosed in a charge cycle and discharge the battery cell in a discharging cycle,
a measuring part configured to measure voltages and currents of the battery cell in the charge cycle, and measure voltages and currents of the battery cell in the discharging cycle, and
a controller configured to generate a charge/discharge differential profile based on the voltages and currents of the battery cell measured in the charge cycle and the discharge cycle, extract an anode half-cell and a cathode half-cell having a charge/discharge differential profile matching the charge/discharge differential profile of the battery cell by referencing the anode database and the cathode database, and estimate a full charge state for each of the cathode and anode of the battery cell based on information of the extracted anode half-cell and the cathode half-cell.

2. The electrode potential estimation device as claimed in claim 1, wherein the controller is configured to:
extract charge/discharge differential profiles of candidate anode half-cells from the anode database,
extract charge/discharge differential profiles of candidate cathode half-cells from the cathode database,
generate charge/discharge differential profiles of candidate full cells by combining each of charge/discharge differential profiles of the candidate anode half-cells with each of charge/discharge differential profiles of the candidate cathode half-cells, and
extract the anode half-cell and the cathode half-cell through matching each of charge/discharge differential profiles of each candidate full cells with the charge/discharge differential profile of the battery cell.

3. The electrode potential estimation device as claimed in claim 2, wherein:
the controller is configured to determine a charge/discharge differential profile of one candidate full cell that has a matching rate that is higher than or equal to a set matching rate with the charge/discharge differential profile of the battery cell and has a highest matching rate, among the charge/discharge differential profiles of the candidate full cells, and
the extracted anode half-cell and cathode half-cell correspond to the anode half-cell and cathode half-cell corresponding to the determined one candidate full cell.

4. The electrode potential estimation device as claimed in claim 2, wherein the controller is configured to extract a charge/discharge differential profiles of the candidate anode half-cells from the anode database based on at least one of the material characteristics of anode active materials of the battery cell, a C-rate, and a charge/discharge voltage, and extract a charge/discharge differential profiles of the candidate cathode half-cells from the cathode database based on the charge/discharge voltage of the battery cell and charge/discharge voltages of the candidate anode half-cells.

5. The electrode potential estimation device as claimed in claim 1, wherein the controller is configured to estimate capacities of the battery cell based on the currents of the battery cell, generate a charge/discharge profile representing the relationships between the voltages and capacities of the battery cell, and generate the charge/discharge differential profile based on the charge/discharge profile.

6. The electrode potential estimation device as claimed in claim 1, wherein the material characteristics of the anode active materials comprise an addition ratio of silicon.

7. A method for estimating an electrode potential of a battery cell in an electrode potential estimation device connected to the battery cell to be diagnosed, the method comprising:
charging the battery cell in a charge cycle and discharging the battery cell in a discharge cycle,
measuring voltages and currents of the battery cell during the charging cycle,
measuring voltages and currents of the battery cell during the discharge cycle,
generating a differential profile representing relationships between voltage change rates for unit capacities and capacities of the battery cell based on the voltages and currents of the battery cell measured in the charge cycle or the discharge cycle, respectively,
extracting an anode half-cell and a cathode half-cell having a differential profile matching the differential profile of the battery cell by referencing an anode database storing differential profiles for anode half-cells and a cathode database storing differential profiles for cathode half-cells, and
estimating a full charge state for each of a cathode and an anode of the battery cell based on information of the extracted cathode half-cell and anode half-cell.

8. The method as claimed in claim 7, further comprising:
setting at least one of material characteristics of anode active materials, a C-rate, and a charge/discharge voltage as variables, and obtaining a differential profile of an anode half-cell while changing at least one variable, and
setting at least one of material characteristics of cathode active materials, a C-rate, and a charge/discharge voltage as variables, and obtaining a differential profile for cathode half-cell while changing at least one variable.

9. The method as claimed in claim 8, wherein the extracting comprises:
extracting differential profiles of candidate anode half-cells from the anode database,
extracting differential profiles of candidate cathode half-cells from the cathode database,
generating differential profiles of candidate full cells by combining each of the differential profiles of the candidate anode half-cells and each of the differential profiles of the candidate cathode half-cells, and
extracting the anode half-cell and the cathode half-cell by matching the differential profile of each of the candidate full cells with the differential profile of the battery cell.

10. The method as claimed in claim 9, wherein the extracting the anode half-cell and the cathode half-cell by matching comprises:
determining one candidate full cell which has a matching rate that is higher than or equal to a set matching rate with the differential profile of the battery cell and has a highest matching rate, among the differential profiles of the candidate full cells, and
extracting the anode half-cell and the cathode half-cell corresponding to the one candidate full cell.

11. The method as claimed in claim 9, wherein:
the extracting differential profiles of candidate anode half-cells comprises extracting the differential profiles of the candidate anode half-cells from the anode database based on at least one of the material characteristics of the anode active materials, the C-rate, and the charge/discharge voltage of the battery cell, and
the extracting differential profiles of candidate cathode half-cells comprises extracting the differential profiles of the candidate cathode half-cell from the cathode database based on the charge/discharge voltage of the battery cell and the charge/discharge voltages of the candidate anode half-cells.

12. The method as claimed in claim 7, wherein the differential profile is one of a charge differential profile and a discharge differential profile.

13. The method as claimed in claim 7, wherein the generating the differential profile comprises:
estimating capacities of the battery cell based on the currents of the battery cell,
generating a charge/discharge profile representing the relationships between the voltages and capacities of the battery cell, and
generating the differential profile based on the generated charge/discharge profile.

14. The method as claimed in claim 7, wherein the material characteristics of the anode active materials comprise an addition ratio of silicon.
